(19) United States
(12) Patent Application Publication
(10) Pub. No.: US 2016/0044809 A1
(43) Pub. Date: Feb. 11, 2016

(54) SUPPORT MECHANISM FOR PORTABLE ELECTRONIC DEVICES

(71) Applicant: MOHAMMED MAHER ISSA DAULEH, Doha (QA)

(72) Inventor: MOHAMMED MAHER ISSA DAULEH, Doha (QA)

(21) Appl. No.: 14/455,356

(22) Filed: Aug. 8, 2014

(51) Int. Cl. H05K 5/02

(52) U.S. Cl. CPC H05K 5/0234; H05K 5/0226

(57) ABSTRACT

The present invention relates to a support mechanism that could be attached to or integrated with portable electronic devices, such as laptop computers and portable Digital Video Disc (DVD) players, wherein such mechanism enables the user to adjust the tilt of his/her portable device with reference to the surface of his/her working space. The mechanism of the present invention comprises at least one movable supporting member; at least one joint; and at least one fixing means, wherein said joint connects the movable supporting member to a bottom surface of a portable electronic device. The support mechanism of the present invention provides flexibility to users and increases the durability of the portable device.

### BACKGROUND

1. Field of the Invention

The present invention relates to portable electronic devices supporting mechanisms, and more particularly to those mechanisms that are used to adjust the tilt of the portable electronic device with reference to the user's workspace surface.

2. Description of the Related Art

Over the past couple of decades numerous technological advancements have occurred. These advancements have caused a wide spread use of portable electronic devices such as laptop computers, Digital Video Disc (DVD) players, etc. These portable devices may harm the user's ergonomics, and they have the drawback of being less durable than equivalent non-portable devices.

For these reasons, there are numerous conventional solutions found in the art related to portable electronic device supporting mechanisms and structures. These supporting mechanisms and structures aim at reducing the harm that affects the user's ergonomics. For instance, among these conventional solutions, there is provided a portable riser for supporting a laptop computer or other article at an angle to a supporting surface. The riser includes a base and lid attached to each other by a double hinge. Arc shaped legs deploy form the riser when the lid is moved from a closed position to an deployed position a position where the lid rests against the opposite side of the base. The legs are formed by deforming a sheet of flexible material that lies between the base and a cover plate. The lid and the sheet of flexible material are coupled to each other so that when the lid is moved from the closed to the deployed position, the sheet of material is deployed.

In another conventional solution, there is provided a stand for supporting a laptop computer at different tilt angles may include a top plate with a trapezoidal shape including a number of riser clusters arranged along a narrower parallel side of the top plate. Each one of the riser clusters may be configured to fit within a riser element and hold the riser element. A bottom plate with a trapezoidal shape may be connected to the top plate by a connector that allows the top plate to rotate relative to the bottom plate. A number of laptop supports may be connected to a wider parallel side of the top plate and configured to support one end of the laptop in a slip-resistant manner. At least two riser elements may be stacked respectively on at least two riser clusters. At least two riser caps may be stacked respectively over the at least two riser elements to support an opposite end of the laptop in a slip-resistant resistant manner and at an elevation higher than the one end of the laptop.

The above-mentioned conventional solutions could not be integrated with portable devices to become in one piece. Therefore, it would be impossible to handle the portable device along with the support structure simultaneously in one hand.

### SUMMARY

Therefore, it is an object of the present invention to provide a supporting mechanism for portable electronic devices that could be integrated with or attached to such devices.

It is an aspect of the present invention to have a support mechanism for portable electronic devices such as laptop computers and portable Digital Video Disc (DVD) players that enables a user to control the tilt of the his/her portable electronic device with reference to the surface of his/her workspace.

As another aspect of the present invention, there is provided a support mechanism for portable electronic devices such as laptop computers and portable Digital Video Disc (DVD) players that increases the durability of such devices by allowing air to pass all over the perimeter of such devices, thus more heat can be dissipated, which will accordingly increase the durability of such devices' hardware.

It is another aspect of the present invention to have a support mechanism for portable electronic devices such as laptop computers and portable Digital Video Disc (DVD) players that is light in weight.

As another aspect of the present invention, there is provided a support mechanism for portable electronic devices such as laptop computers and portable Digital Video Disc (DVD) players comprising at least one movable supporting member; at least one joint; and at least one fixing means.

Preferably, the mechanism of the present invention is made of a light weight material rigid material such as plastic or aluminum.

Preferably, said at least one movable supporting member has at least one degree of freedom.

Preferably, said at least one movable supporting member can move between an opened position and a closed position.

Preferably, said at least one movable supporting member is attached to a portable electronic device base.

Preferably, said at least one joint comprises a hinge.

Preferably, said at least one joint connects said at least one supporting member to said portable electronic device base.

Preferably, said at least one fixing means keeps the at least one movable member in the closed position.

Preferably, said at least one supporting member has a regular shape.

Preferably, said at least one supporting member has a curved shape.

### BRIEF DESCRIPTION OF THE DRAWINGS

The invention will be described with reference to the accompanying drawings, which illustrate a preferred embodiment of the present invention without restricting the scope of the invention thereof, and in which:

FIG. 1 is a bottom perspective view of two support mechanisms for portable electronic devices configured according to a preferred embodiment of the present invention, wherein such mechanisms are attached to a portable electronic device with a supporting members being in an open position.

FIG. 2 is a bottom perspective view of two support mechanisms for portable electronic devices configured according to a preferred embodiment of the present invention, wherein such mechanisms are attached to a portable electronic device with a supporting members being in a closed position.

FIG. 3 is a bottom exploded view of a support mechanism for portable electronic devices configured according to a preferred embodiment of the present invention.

### DETAILED DESCRIPTION OF THE PREFERRED EMBODIMENT

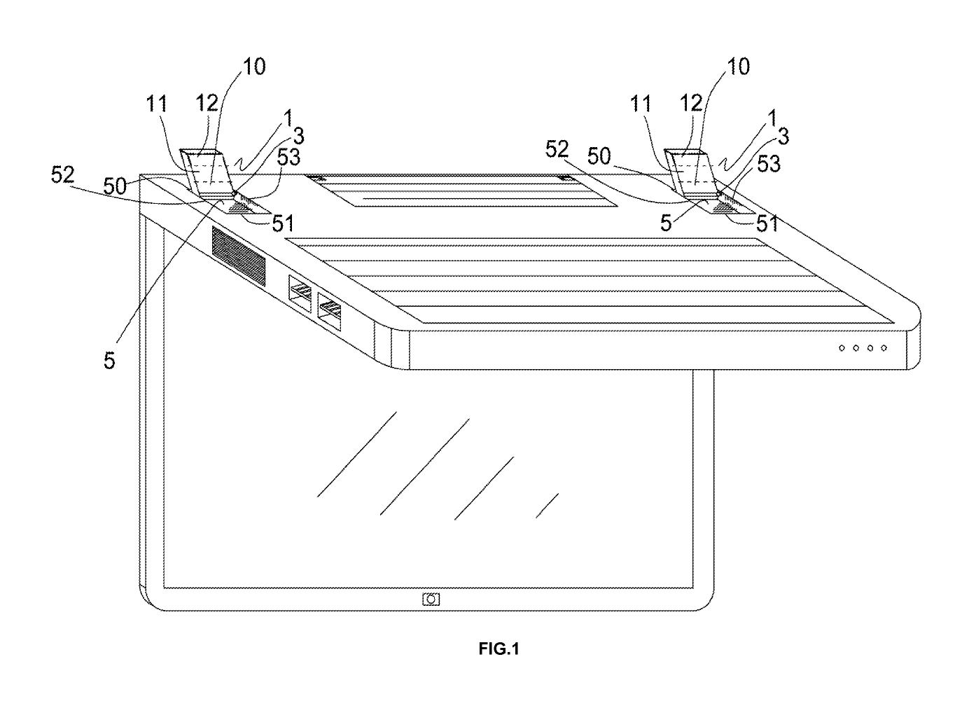

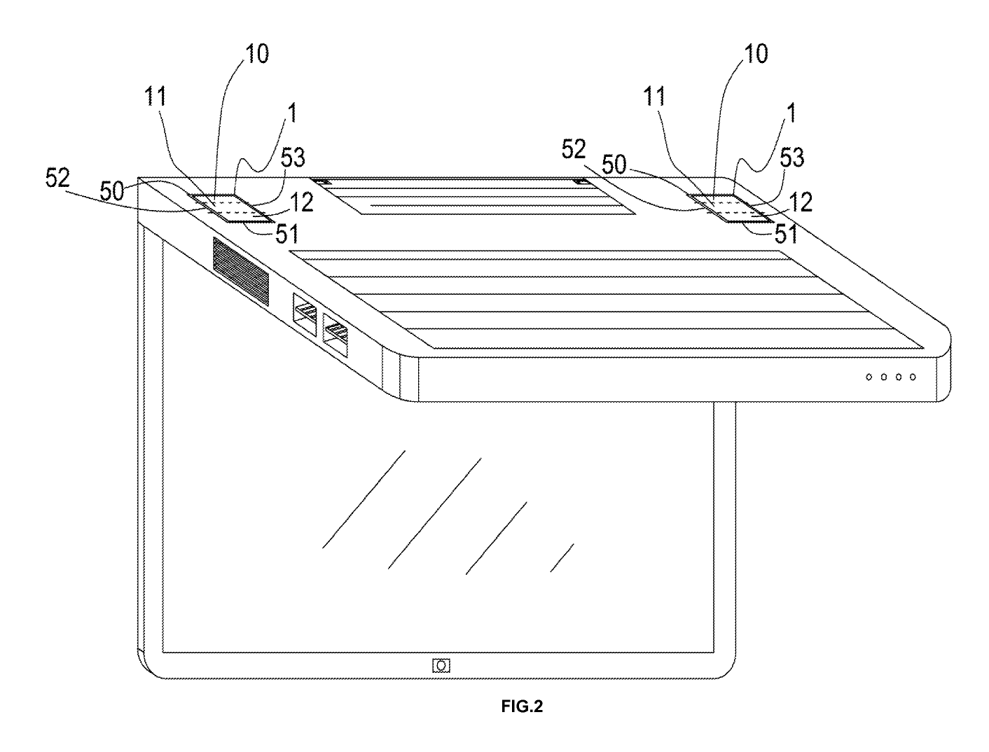

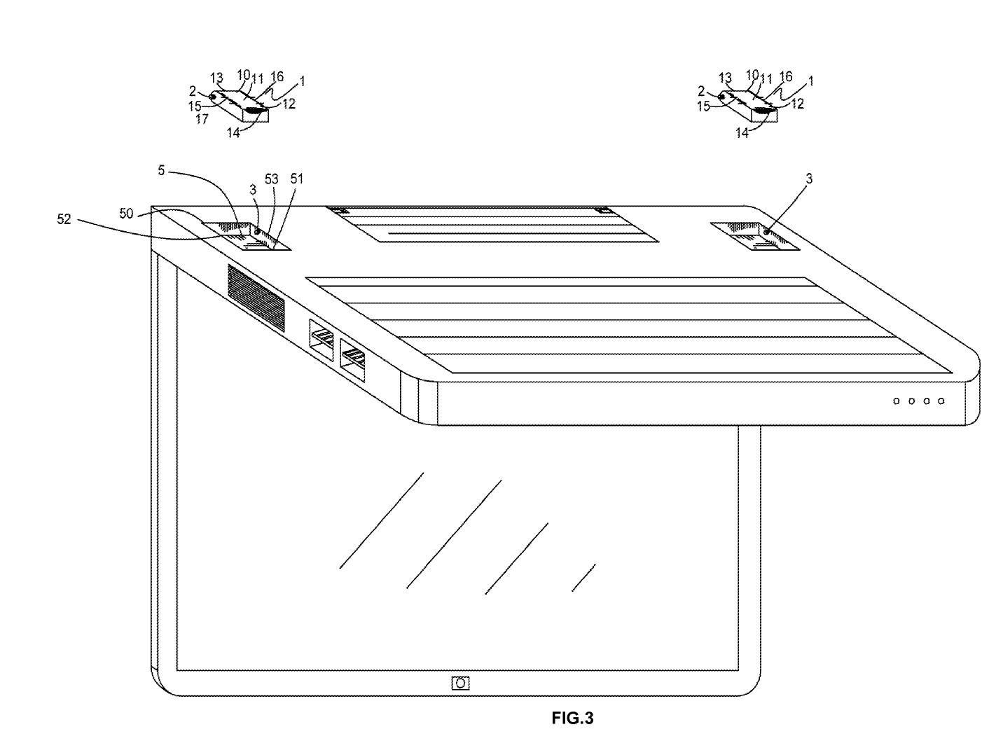

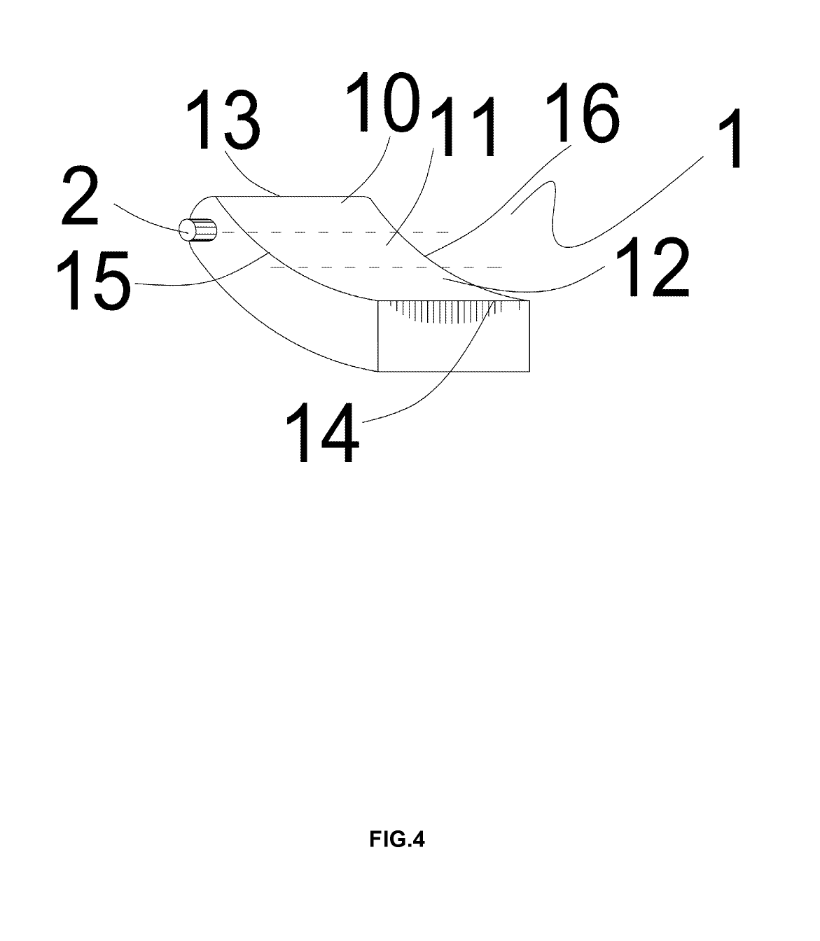

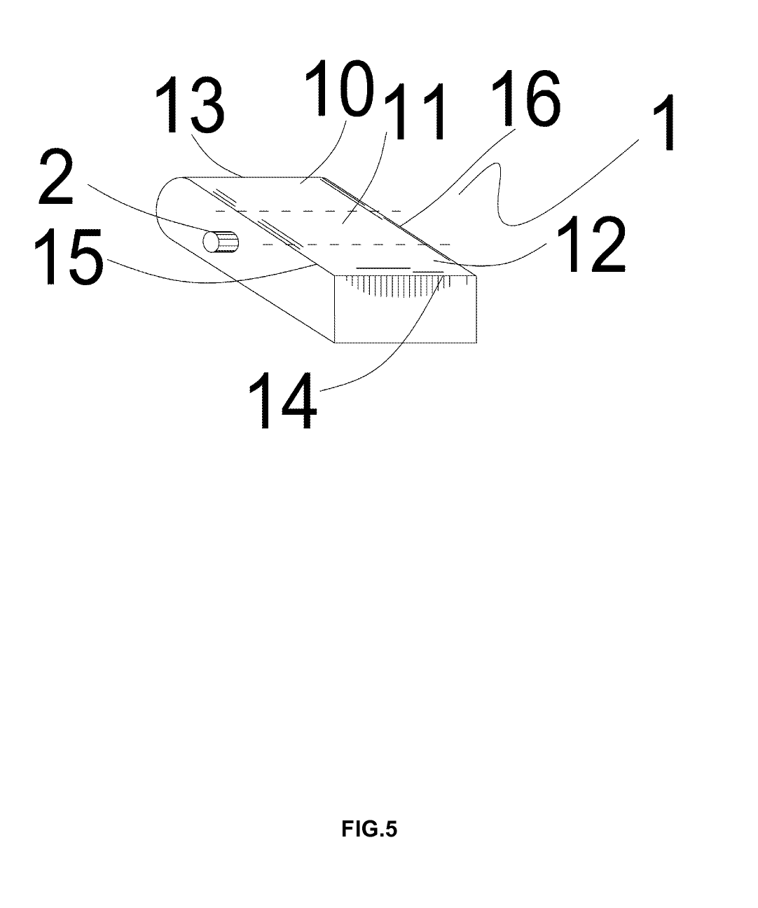

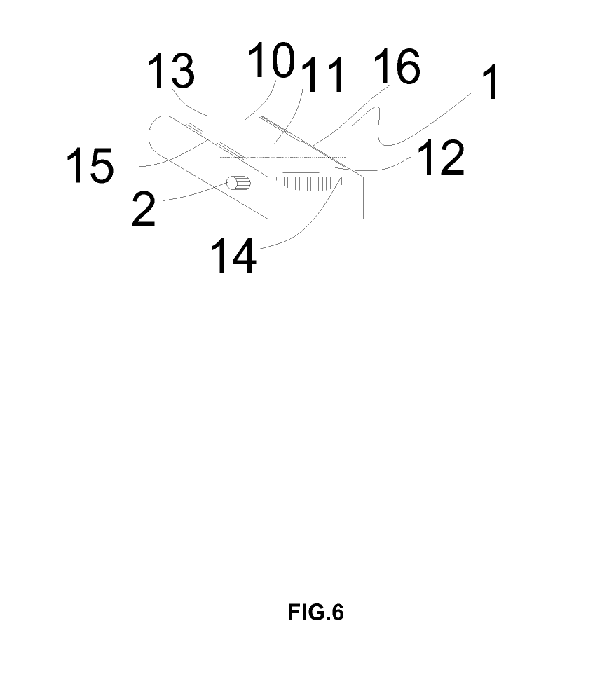

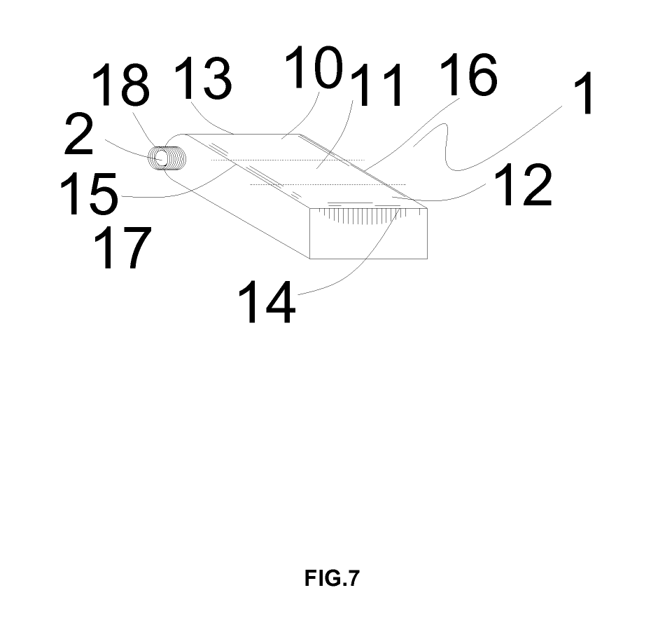

FIGS. 1, 2, and 3 illustrate a support mechanism for portable electronic devices configured according to a preferred embodiment of the present invention, wherein such embodiment comprises at least one movable supporting member 1, wherein such supporting member moves between an opened position and a closed position, wherein such base can be integrated with the portable device's bottom surface; at least one joint 2, wherein such joint connects the movable supporting member 1 to portable electronic device base. The preferred embodiment of the present invention also comprises at least one fixing means 3.

In the preferred embodiment of the present invention, the movement of said at least one movable supporting member 1 is confined, such that the at least one movable supporting member 1 is free to move between an angle of 0° (for closed position) and an angle of 130° (for opened position) with reference to the portable electronic device bottom surface.

Said at least one movable supporting member 1 has a regular-shaped cross-section.

Said at least one movable supporting member 1 could be either curved or straight.

Said at least one movable supporting member 1 has an upper portion 10; an intermediate portion 11; a lower portion 12; an upper edge 13; a lower edge 14; wherein the upper and lower edges 13 and 14 are parallel; and two parallel lateral edges 15 and 16.

In the preferred embodiment of the present invention, when said at least one movable supporting member 1 is in the closed position, it resides in an opening 5 found in the portable device's bottom surface, wherein said opening 5 has an upper edge 50, a lower edge 51, and two lateral parallel edges 52 and 53.

In the preferred embodiment of the present invention, said lower edge 15 of said at least movable supporting member 1 is parallel to the lower edge 51 of said opening 52 when said at least one movable supporting member is in the opened position.

In another embodiment of the present invention, said lower edge 15 of said at least movable supporting member 1 is parallel to said lateral edges 52 and 53 of said opening 5 when said at least one movable supporting member is in the opened position.

Said at least one joint 3 has at least one degree of freedom such as a hinge, wherein such joint enables said at least one movable supporting member to move between the opened and closed positions.

In the preferred embodiment of the present invention, said at least one joint 3 is positioned at the upper portion 10 of said at least one movable supporting member 1.

In another preferred embodiment of the present invention, said at least one joint 3 is positioned at the intermediate portion 11 of said at least one movable supporting member 1.

In another preferred embodiment of the present invention, said at least one joint 2 is positioned at the lower portion 12 of said at least one movable supporting member 1.

In the preferred embodiment of the present invention, said at least one fixing means 3 keeps said at least one movable member 1 in the closed positioned, wherein such fixing means 3 comprises at least one protrusion positioned at said least one base that restricts the free movement of the at least one movable member 1, and causes the movement of such movable member 1 to range between the opened to the closed position to take place due to a force imposed by the user's hand.

In another preferred embodiment, said at least one fixing means 3 comprises a spring that is connected from one end to the base 2 and from the other end to the movable supporting member 1.

In the preferred embodiment of the present invention, said at least movable member 1 has a height ranging between 0.5 cm and 3 cm, and a width ranging from 1 cm up to the same width of the portable device.

In the preferred embodiment of the present invention, the tilt caused by the support mechanism of the present invention when said at least movable supporting member 1 is in the closed position is zero.

The support mechanism for portable electronic devices of the present invention decreases the harms caused to the user's agronomics associated with the frequent use of such portable devices by giving the user the flexibility to adjust the tilt of the device.

The support mechanism for portable electronic devices of the present invention increases the durability of the portable devices hardware by enhancing the dissipation of heat to the surrounding environment since such mechanism allows air to flow over the perimeter of the portable device.

The support mechanism for portable electronic devices of the present invention is made of a lightweight rigid material, preferably aluminum or plastic.

While the present invention has been described in details and with reference to specific embodiments thereof, it will be apparent to one skilled in the art that various additions, omissions and modifications can be made without departing from the spirit and scope thereof.

Although the above description contains many specificities, these should not be construed as limitations on the scope of the invention but is merely representative of the presently preferred embodiments of this invention. The embodiment(s) of the invention described above is(are) intended to be exemplary only. The scope of the invention is therefore intended to be limited solely by the scope of the appended claims.

1. A support mechanism that could be integrated with a bottom surface of portable electronic devices and enables the user to adjust the tilt of his/her portable device with reference to the surface of his/her working space by elevating a rear portion of said portable device, said mechanism comprises:
at least one movable supporting member with an upper portion, an intermediate portion, and a lower portion;
at least one joint; and
at least one fixing means, wherein said mechanism is positioned at said rear portion of said portable electronic device.

2. The support mechanism of claim 1, wherein said at least movable supporting member moves between an open position and a closed position.

3. The support mechanism of claim 1, wherein said at least one movable supporting member has a regular-shaped cross-section.

4. (canceled)

5. The support mechanism of claim 1, wherein said at least one movable supporting member has a curved shape.

6. The support mechanism of claim 1, wherein said at least one movable supporting member resides in an opening configured in a bottom surface of said portable electronic device, wherein said opening comprises an upper edge, a lower edge, and two parallel lateral edges.

7. The support mechanism of claim 1, wherein said at least one movable supporting member is connected to said opening by said at least one joint.

8. The support mechanism of claim 1, wherein said at least one joint has at least one degree of freedom.

9. The support mechanism of claim 1, wherein said at least one joint comprises a hinge.

10. The support mechanism of claim 1, wherein said at least one joint is connected to said upper portion of said at least one movable supporting member.

11. The support mechanism of claim 1, wherein said at least one joint is connected to said intermediate portion of said at least one movable supporting member.

12. The support mechanism of claim 1, wherein said at least one joint is connected to said lower portion of said at least one movable supporting member.

13. The support mechanism of claim 1, wherein said at least one fixing means comprises at least one protrusion positioned at said at least one fixing means restricts the free movement of the at least one movable member.

14. The support mechanism of claim 1, wherein said at least one fixing means causes the movement of said movable supporting member to range between said open and closed positions, and wherein such movement takes place due to a force imposed by the user's hand.

15. The support mechanism of claim 1, wherein said at least one fixing means comprises a spring with a first end and a second end, said spring connected to said at least one movable supporting member from said first end, and to one of said lateral edges of said opening from said second end.

16. (canceled)

17. The support mechanism of claim 1, wherein said support mechanism is made of lightweight rigid material.

18. The support mechanism of claim 17, wherein said lightweight rigid material comprises plastic.

19. (canceled)

20. The support mechanism of claim 6, wherein said at least one movable supporting member is connected to said opening by said at least one joint.

21. The support mechanism of claim 6, wherein said at least one fixing means comprises at least one protrusion positioned at said any of said lateral edges of said opening, said at least one fixing means restricts the free movement of the at least one movable member.

22. The support mechanism of claim 2, wherein said at least one fixing means causes the movement of said movable supporting member to range between said open and close positions, and wherein such movement takes place due to a force imposed by the user's hand.

23. The support mechanism of claim 1, wherein said at least one fixing means comprises a spring with a first end and a second end, said spring is connected to said at least one movable supporting member from said first end, and to one of said lateral edges of said opening from said second end.
